(19) United States
(12) Patent Application Publication
(10) Pub. No.: US 2003/0123673 A1
(43) Pub. Date: Jul. 3, 2003

(54) ELECTRONIC SOUND EQUIPMENT

(76) Inventor: TSUNESHIGE KOJIMA, TOKYO (JP)

Correspondence Address: STANLEY R MOORE, JENKENS & GILCHRIST, 3200 FOUNTAIN PLACE, DALLAS, TX, 752022799

(21) Appl. No.: 08/930,918

(22) PCT Filed: Feb. 13, 1997
(86) PCT No.: PCT/JP97/00368

(30) Foreign Application Priority Data
Feb. 13, 1996 (JP) 8-49490

(51) Int. Cl. H04R 5/00; H03G 11/00; H04B 3/00

(52) U.S. Cl. 381/1; 381/26; 381/80; 381/55

(57) ABSTRACT

This invention relates to the electronic sound equipment which individually records and reproduces the instruments (sound sources) composing an orchestra or an assemble, and creates delicate and powerful sounds with clearly position of sound. It comprises the record and reproduction section with the same number of the channels as the music sources (including the case of one instrument for several channels), and at least one speaker (non directional speaker system is recommended) for each channel of this record and reproduction section, characterized in by placing the speakers freely on the wall, floor or ceiling, the music scene which is extremely close to a live performance is reproduced at a hall or at home.

### BACKGROUND OF THE INVENTION

1. Field of the Invention

This invention relates to the electronic sound equipment which records, generates and reproduces sound field which is close to a live performance or more effective at home, a concert hall, or on a field.

2. Background Art

A prior sound equipment such as a stereo is to reproduce a sound from music source recorded in record mediums such as a record, a magnetic tape, and a CD, and a sound from a synthesizer. Such equipment in principle records the sound which is picked up by the microphones through two systems (two channels) of right and left, (or the sound which is mixed up into two systems by synthesizer and others) and reproduces a sound scene by outputting the sound through the speakers of the two systems (two channels).

Currently the sound system for movie theaters has several channels to produce the sound of a car and a train passing through, but the system to make sound positions is the same as said two-channel system in principle. In other words, the difference of strength and phase of sounds through two speakers produces a sound position and a sound scene .

The sounds generated from tens and hundreds of instruments (sound sources) such as in orchestra, are mixed and recorded as the signals of two channels, and this sound of two-channel is reproduced through the two speakers as if those sound sources exist before one's eyes in simulation. The multitudinous sound source produced by a synthesizer which produces artificial sounds of various instruments is also mixed down into two systems (two channels) by a mixer and others to be recorded and reproduced in the same way mentioned above.

However, since all sound sources are recorded and reproduced as the signals of two channels, it is difficult to reproduce delicate sounds like the sound generated when a resin coated violin bow rubs strings or powerful sounds, which cannot be heard at all other than a live performance. Also because of said reproduction system of two channels, the sounds are unstable for lacking of the clearness of the sound source and the definite position, and for spreading too widely or being missed out in the middle. Especially, the difference of listening position or volume of the sounds make these phenomena stand out.

Considering above points, this invention aims to provide the electronic sound equipment avoiding the foregoing problems, which records and reproduces each individual instrument (sound source) composing such as an orchestra and an ensemble, and creates delicate and powerful sounds and sound scenes with clear sound positions.

### SUMMARY OF THE INVENTION

This invention comprises a record and reproduction section which has the same number of channels as the sound sources (including an instrument with several channels) and more than one speaker system for each channel (especially non-direction speaker system is recommended. The speaker system is expressed just as a speaker hereinafter), and characterized in by putting the speakers any places such as on the wall, floor, and ceiling, in other words, by actually placing the sound in space, reproducing or newly creating a sound scene. Thus, it is composed to reproduce a sound which is extremely close to a live performance at a hall, at home or on a field.

The invention according to claim 2 is fitted with the large volume cut safety device in the multi-channel processor between the record and reproduction section and the speakers to avoid excess sounds by troubles of the system or noises which cannot be accepted physically by listeners.

### BRIEF DESCRIPTION OF THE DRAWINGS

FIG. 1 is an explanatory diagram showing this invention briefly,

FIG. 2 is an explanatory diagram showing an example of the processor, and

FIG. 3 is an explanatory diagram of the processor fitted with the large volume cut safety device.

### BEST MODE FOR CARRYING OUT THE INVENTION

This invention is explained in detail based on the attached drawings.

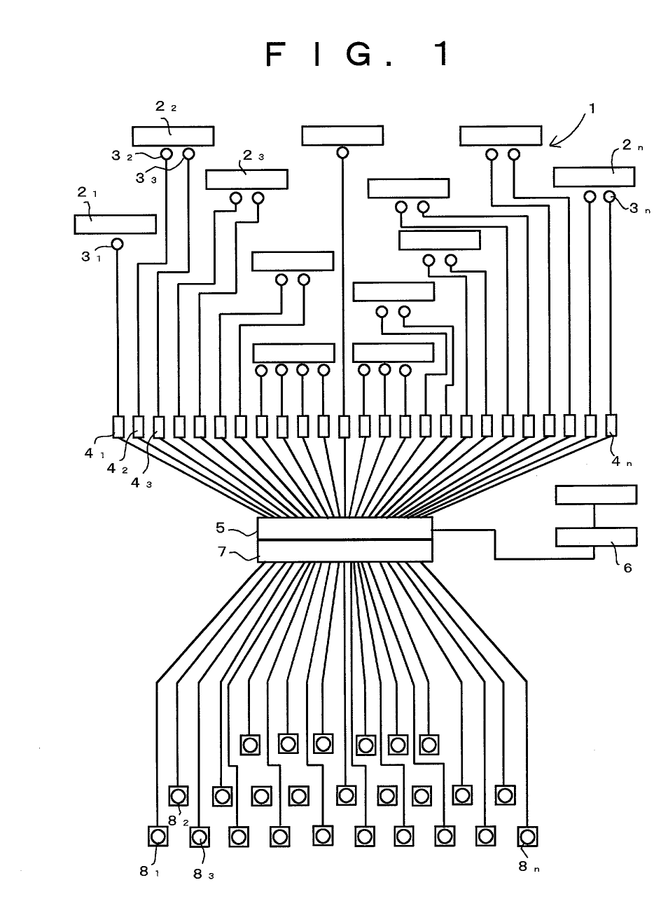

FIG. 1 shows a typical organization of an orchestra.

Although there are various ways to compose an orchestra 1, it is typically organized with stringed instruments consisting of a violin, a viola, a cello, a contrabass and a harp, wind instruments consisting of a trumpet, a clarinet, a flute, a trombone, a bassoon and an oboe, and percussion instruments consisting of a timpani and others, and each individual instrument is considered as an important sound source 2₁, 2₂ . . . 2ₙ.

Although the number of each sound source 2₁, 2₂ . . . 2ₙ. is not described in the figure, it is composed with a large number of instruments.

The sound from said sound source 2₁, 2₂ . . . 2ₙ is collected through the same number of microphones 3₁, 3₂ . . . 3ₙ. as the sound source, and carried into pre-amps for the microphones 4₁, 4₂ . . . 4ₙ, adjusted to the audio signal of regulated level (analog signal or digital signal) where the MIDI signal is added to each channel (this is not necessarily), and then recorded by the multi-channel record and reproduction equipment 5 with the same number of channels as the sound source 2₁, 2₂ . . . 2ₙ(by analog system or digital system).

The multi-channel record and reproduction equipment 5 does not need to comprise physically the same number of recording trucks as channels because it has enough recording and reproducing buffers so that foregoing numbers of channels separately and independently when it records or reproduces and that said channels respectively can record and reproduce at once.

The multi-channel record and reproduction equipment 5 can create and reproduce multi-channel record mediums such as magnetic tape, CD, hard disk and memory card.

Since the figure shown in the embodiment is based on a logical concept, it shows the situation when sounds are recorded from orchestra, but it is naturally possible to record each sound source separately in time and in space.

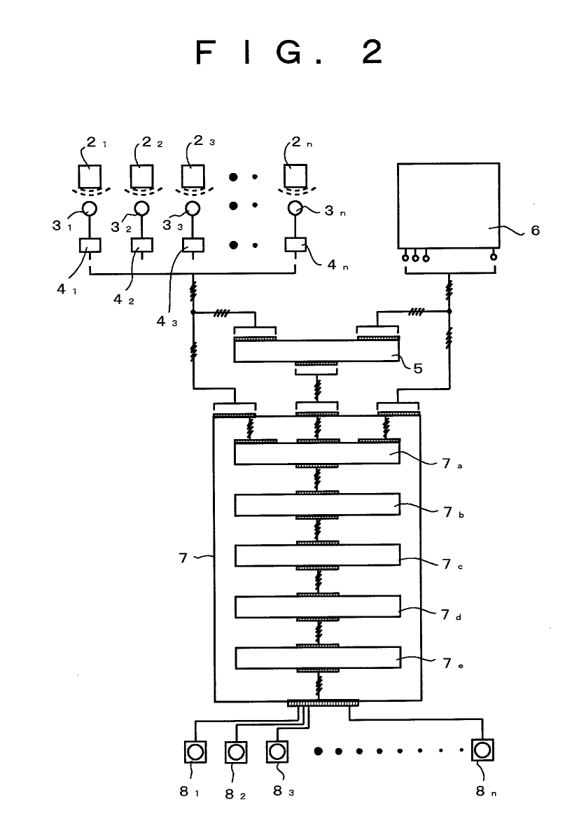

Said sound source can be taken out from the synthesizer 6 (including what is called sound sources or samplers) as shown in FIGS. 1 and 2. The synthesizer 6 is an electronic instrument which has a network that generates various sounds depend on the player's intentions or the computer commands (sequencers), and the audio signal and the MIDI signal can be taken out from the synthesizer 6 to record and reproduce in the same way mentioned above.

The feature of the synthesizer 6 mentioned above in this invention is comprising the ports which can output the same number of instruments (timbrels) independently at once. Even with a current synthesizer with a few ports, the multi-channel record and reproduction equipment 5 can record the necessary number of music instruments repeatedly, so when it comes to reproducing, it can reproduce the sounds from all the necessary music instruments at once.

The audio signal (the MIDI signal) recorded in a record medium of the multi-channel record and reproduction equipment 5 is reproduced in the same section 5, and put out from the speakers 8 ₁, 8₂ . . . 8ₙ through the processor 7 (including controller, effector, switches, pre-amp, output amplifier, and the large volume cut safety device as necessary) shown in the FIGS. 1 and 2. The speakers 8₁, 8₂ . . . 8ₙ are equipped by one or more to each channel in the same number as the sound source 2₁, 2₂ . . . 2ₙ, so if there are 120 sound sources, for example, the number of the speakers will also be 120 or more.

Also, it is possible that said multi-channel record and reproduction equipment 5 makes the sounds from a microphone or a synthesizer put out from the speakers 8₁, 8₂ . . . 8ₙ through the processor 7 (including controller, effector, switcher, pre-amp, output amplifier, and the large volume cut safety device as necessary) without go through the recording or reproducing networks.

Said processor 7 naturally indicates the multi-channel processor, and it can work with the each channel separately at once. As shown in FIG. 2, the processor 7 is composed with the following sections; the input switching mode selecting and mixing control section 7a where the output signal of the audio signal or the MIDI signal from the microphone 2 or the synthesizer 6 is switched or mixed, the effecting section 7b where the audio signal from each channel is processed to create various effects, the switching section 7c where the speaker to put out the sound of the channel is selected and set (It is switched by the designated channel signal which is attached to each sound source. This is not necessarily by the designated channel signal and manual switch is also used), the pre-amp section 7d which has the same number of the pre-amp as said channels, and the main (output) amplifier section 7e, characterized in comprising the same number of connectors of speakers for output lines as speakers corresponding to the number of said channel.

Each part, 7a-7e, of said processor 7 is an independent module and physically separated, and it can be connected each other with the same number of wire or wireless lines as the channels.

Said processor 7 has another advantageous feature when the output from an amplifier or a speaker of one or more channels is not enough, other amplifiers or speakers of other channels around it can be set to support the output.

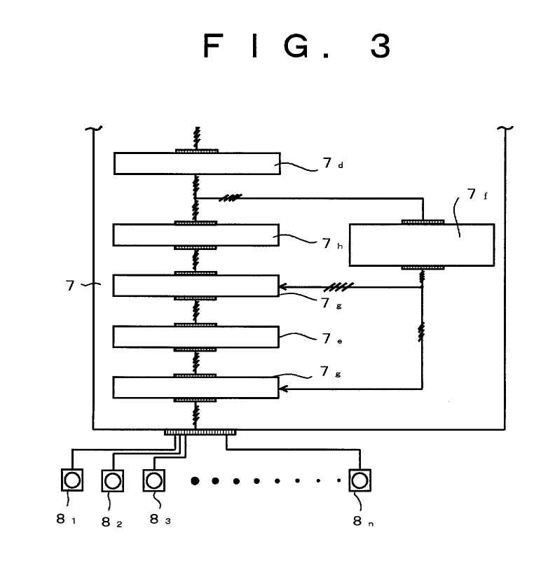

As shown in the FIG. 3, the large volume cut safety device can be placed between the pre-amp section 7d and the main (output) amplifier section 7e to prevent speakers outputting the too loud sound for human beings to tolerate. Said device is composed with the control section 7f where the total sound level for each channel in an appropriate time frame is calculated, and the switching section 7g where the channels are cut actually. The safety level can be raised by placing the switching section 7g at the output side of the main amplifier section 7e.

Said control section 7f can have the function of the signal delaying section 7h to each channel depending on the control time which is necessary to calculate. Whether cutting the channels entirely or partly depends on the way of control, and so does the revival way.

This invention has another feature that it can also cover the former system of the theory with two channels for record and two channels for reproduction. Accordingly, by using the former system to inside or outside of this system at the same time, they can improve each other as a mutual effect. Especially, the effect of a reverberation is a remarkable point of in the system of the present invention.

Therefore, the speakers at home, at a concert hall, or on a field should be placed which could be rearranged freely by preference (including physical movement and movement by replacing into input terminal) depend on purposes.

Now the using modes of the equipment is expressed.

(1) When there is an actual sound source (music instrument).

a) Recording mode

Sound source 2₁→Microphone 3₁→Record and reproduction equipment 5 (music instrument)

Sound source 2₂→Microphone 3₂→Record and reproduction equipment 5 (music instrument)

Sound source 2₃→Microphone 3₃→Record and reproduction equipment 5 (music instrument)

Sound source 2ₙ→Microphone 3ₙ→Record and reproduction equipment 5 (music instrument)

b) Reproduction mode

Record and reproduction equipment 5₁→Processor 7→Speaker 8₁

Record and reproduction equipment 5₂→Processor 7→Speaker 8₂

Record and reproduction equipment 5₃→Processor 7→Speaker 8₃

Record and reproduction equipment 5ₙ→Processor 7→Speaker 8ₙ Or

Sound source 2₁→Microphone 3₁→Processor 7→Speaker 8₁ (music instrument)

Sound source 2₂→Microphone 3₂→Processor 7→Speaker 8₂ (music instrument)

Sound source 2₃→Microphone 3₃ →Processor 7→Speaker 8₃ (music instrument)

Sound source 2₃→Microphone 3ₙ →Processor 7→Speaker 8ₙ (music instrument)

(2) Record and reproduction mode with the sound source (music instrument) of a synthesizer and others are as follows.

a) Record mode

Sound source (synthesizer)→Effector for synthesizer→Record and reproduction equipment 5

Sound source (synthesizer)→Effector for synthesizer→Record and reproduction equipment 5

Sound source (synthesizer)→Effector for synthesizer→Record and reproduction equipment 5

Sound source (synthesizer)→Effector for synthesizer→Record and reproduction equipment 5

b) Reproduction mode.

Record and reproduction equipment 5→Processor 7→Speaker 8₁

Record and reproduction equipment 5→Processor 7→Speaker 8₂

Record and reproduction equipment 5→Processor 7→Speaker 8₃

Record and reproduction equipment 5→Processor 7→Speaker 8ₙ Or

Sound source (synthesizer)→Processor 7→Record and reproduction equipment 5

Sound source (synthesizer)→Processor 7→Record and reproduction equipment 5

Sound source (synthesizer)→Processor 7→Record and reproduction equipment 5

Sound source (synthesizer)→Processor 7→Record and reproduction equipment 5

The reproduction mode can rearrange the connection between the speakers and sound sources momentary. For example, it is possible to change an arrangement of the music instruments entirely in the middle of the music.

As described above, this invention comprises the record and reproduction section with the same number of channels as music source, and equips one or more speaker for each of those channels. Since each speaker can be placed at any place, it is possible to rearrange the actual music source depend on purposes, which create an entirely new field of music as a result.

Since each sound source (music instrument) can be easily fitted with the adequate speakers in peculiarity, it can create a delicate and powerful music scene that is extremely close to a live performance.

In addition, new effects in visual can be provided by designing the speakers into the shapes of music instruments, or robots playing music. Also the multi-channel recordings in general require a mixer to the compounding operations and works of mixing down, but it can be omitted in this invention.

Because it is possible to create and reproduce the records and record mediums which has same number of channels as the music sources, each sound can be individually processed later. Accordingly, the sound and music data in this invention can add their values, which will increase the utility value when a database is constructed.

Excluding the external recording equipment comprising the mechanical mobile section in the system and the main amplifier, the equipment of the present invention can be accumulated on one or several tips.

The invention has the large volume cut safety device between the multi-channel processor and the record and reproduction section to prevent too loud sound which cannot be accepted by human beings physically by system troubles or noises.

Industrial Applicability

As described above, the electronic sound equipment in the present invention is utilized in orchestra or in the simulation of the former orchestra. It can have music halls used more often, and is utilized for improvement of music education and training of conductors. It is also utilized as a new instruments which is not found in the former sound equipment. The equipment is proper in all kinds of music whether it is a popular music and classical music.

Also the electronic sound equipment in the present invention can omit the compounding operations and works of mixing down by a mixer in the multi-channel recordings, create and reproduce the records and record mediums which has same number of channels as the music sources, increase the value of the sound and music data. Thus it can increase the utility value in constructing a database. Also the equipment of the present invention can be accumulated on one or several tips excluding the external recording equipment comprising the mechanical mobile section in the system, and the main amplifier (output amplifier).

What is claimed is

1. The electronic sound equipment characterizing in comprising a record and reproduction section with the same number of channels as sound sources and at least one speaker for each channel.

2. The electronic sound equipment according to claim 1 characterizing in that a large volume cut safety system is fitted to the multi-channel processor between the record and reproduction section and the speakers.
